(19) United States
(12) Patent Application Publication
(10) Pub. No.: US 2024/0347608 A1
(43) Pub. Date: Oct. 17, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Yi-Cheng Chu, Chiayi City (TW); Chien-Hua Huang, Miaoli County (TW); Katherine H. CHIANG, New Taipei City (TW); Yu-Ming Lin, Hsinchu City (TW); Chung-Te Lin, Tainan City (TW)

(73) Assignee: Taiwan Semiconductor Manufacturing Company, Ltd., Hsinchu (TW)

(21) Appl. No.: 18/299,691

(22) Filed: Apr. 12, 2023

(51) Int. Cl. H01L 29/417; H01L 23/522; H01L 29/40; H01L 29/66; H01L 29/786

(52) U.S. Cl. CPC H01L 29/41733; H01L 23/5226; H01L 29/401; H01L 29/66969; H01L 29/78606; H01L 29/7869

(57) ABSTRACT

A semiconductor device is disclosed. The semiconductor device includes a semiconducting material layer, a gate electrode under the semiconducting material layer, a pair of contact terminals over the semiconducting material layer, and a hydrogen-blocking dielectric layer on the semiconducting material layer. The pair of contact terminals penetrates through the hydrogen-blocking dielectric layer to be in contact with the semiconducting material layer at a contact surface, and the contact surface is substantially coplanar with and levelled with an interface between the hydrogen-blocking dielectric layer and the semiconducting material layer.

### BACKGROUND

In the semiconductor industry, there is constant desire to increase the integration density of integrated circuits. Thin film transistors (TFT) made of oxide semiconductors are an attractive option for back-end-of line (BEOL) integration because thin film transistors may be fabricated under lower temperatures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of an exemplary structure prior to formation of thin film transistor (TFT) devices in accordance with some embodiments of the disclosure.

FIG. 1B is a cross-sectional view of the exemplary structure during formation of the thin film transistors in accordance with some embodiments of the disclosure.

FIG. 1C is a cross-sectional view of the exemplary structure after formation of upper interconnect-level structures in accordance with some embodiments of the disclosure.

FIG. 2 through FIG. 7 are fragmentary cross-sectional views at various stages of formation of a thin film transistor in accordance with some embodiments of the disclosure.

FIG. 8 through FIG. 13 are fragmentary cross-sectional views at various stages of formation of a thin film transistor in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description. Source/drain structure(s) may refer to a source or a drain, individually or collectively dependent upon the context.

The present disclosure is directed to semiconductor devices, and specifically to thin film transistors including one or more capping layers to protect a semiconducting channel layer during subsequent formation of source and drain electrodes, and methods of forming the same.

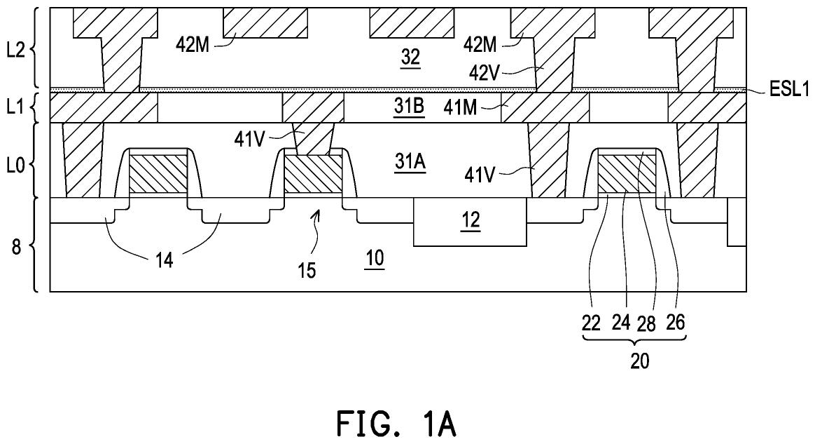

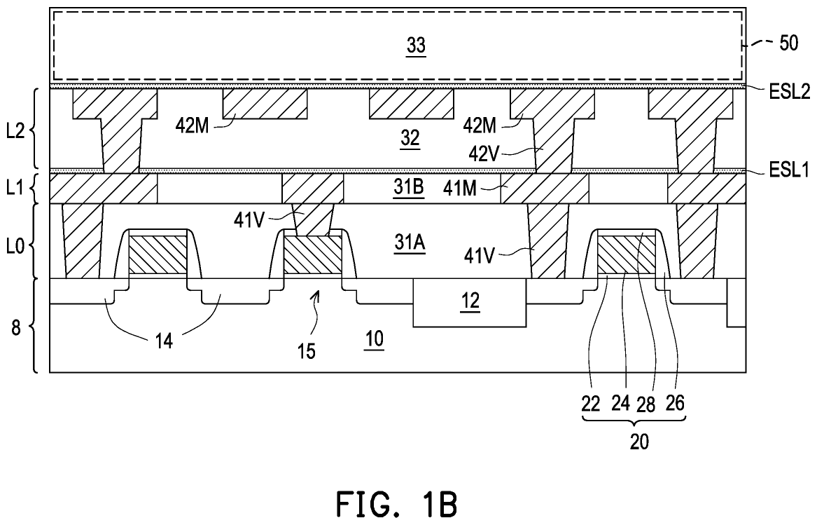

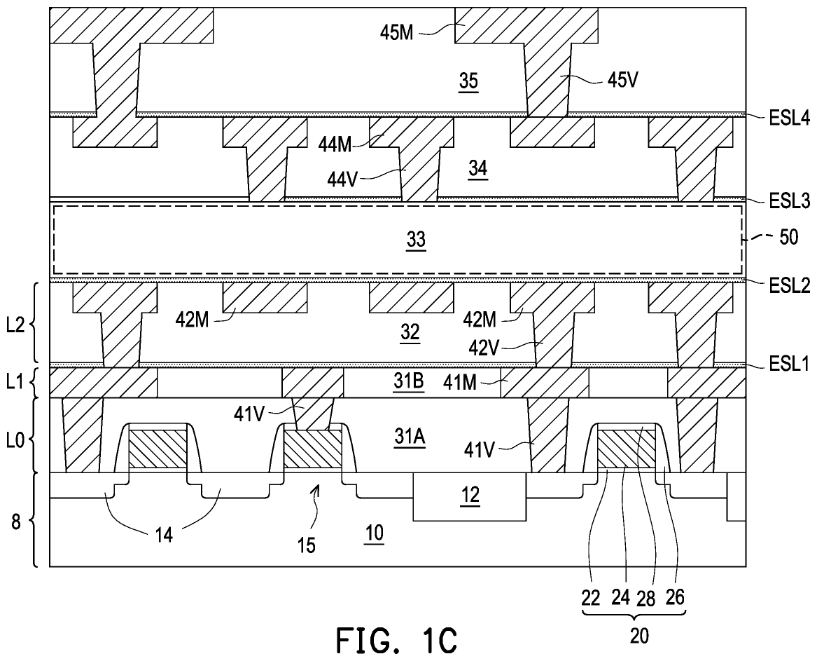

Referring to FIG. 1A, an exemplary structure according to some embodiments of the present disclosure is illustrated prior to formation of a plurality of thin film transistors. The exemplary structure includes a substrate 8 that includes a semiconductor material layer 10. In some embodiments, the substrate 8 includes a bulk semiconductor substrate such as a silicon substrate in which the semiconductor material layer continuously extends from a top surface of the substrate 8 to a bottom surface of the substrate 8, or a semiconductor-on-insulator (SOI) layer including the semiconductor material layer 10 as a top semiconducting material layer overlying a buried insulator layer (such as a silicon oxide layer).

As illustrated in FIG. 1A, the exemplary structure includes various semiconductor devices such as field effect transistors (FETs) may be formed on, and/or in, the semiconductor material layer 10 during FEOL processing. In some embodiments, shallow trench isolation structures 12 are formed in an upper portion of the semiconductor material layer 10 by forming shallow trenches and subsequently filling the shallow trenches with a dielectric material such as silicon dioxide. Other suitable dielectric materials may alternatively be utilized. Various doped wells (not shown) may be formed in various regions of the upper portion of the semiconductor material layer 10 by performing masked ion implantation processes.

In some embodiments, gate structures 20 are formed over the substrate 8 by depositing and patterning a gate dielectric layer, a gate electrode layer, and a gate cap dielectric layer. For example, each gate structure 20 includes a stack of a gate dielectric 22, a gate electrode 24, and a gate cap dielectric 28, which is herein referred to as a gate stack. Dielectric gate spacers 26 may be formed around the gate stacks. Each assembly of a gate stack and a dielectric gate spacer 26 constitutes a gate structure 20.

In some embodiments, ion implantation processes are performed to form extension implant regions, which may include source extension regions and drain extension regions. Additional ion implantation processes may also be performed using the gate structures 20 as self-aligned implantation masks to form deep active regions. Such deep active regions include deep source regions and deep drain regions, for example. In some embodiments, upper portions of the deep active regions overlap with portions of the extension implantation regions. In some embodiments, each combination of an extension implantation region and a deep active region constitutes an active region 14, which may be a source region or a drain region depending on electrical biasing. In some embodiments, a semiconductor channel 15 is formed underneath each gate stack between a neighboring pair of active regions 14. As shown in FIG. 1A, field effect transistors are formed on the semiconductor material layer 10. Each field effect transistor includes a gate structure 20, a semiconductor channel 15 and a pair of active regions 14 (one of which functions as a source region and another of which functions as a drain region). In some other embodiments, metal-semiconductor alloy regions (not shown) are further formed on the top surface of each active region 14.

Various interconnect-level structures may be subsequently formed, which are formed prior to formation of thin film transistors, and are herein referred to as lower interconnect-level structures. In some embodiments, the lower interconnect-level structures include a contact-level structure L0, a first interconnect-level structure L1, and a second interconnect-level structure L2. The contact-level structure L0 includes a contact-level dielectric layer 31A including a dielectric material such as silicon dioxide and various contact vias 41V formed within the contact-level dielectric layer 31A. The contact vias 41V contact a respective one of the active regions 14 or the gate electrodes 24, for example.

The first interconnect-level structure L1 includes a first interconnect-level dielectric layer 31B and a plurality of interconnect metal lines 41M formed within the first interconnect-level dielectric layer 31B. In some embodiments, the first interconnect-level dielectric layer 31B is also referred to as a line-level dielectric layer. As shown in FIG. 1A, the interconnect metal lines 41M and the contact vias 41V are connected, and the interconnect metal line 41M is in contact with a respective one of the contact vias 41V. The second interconnect-level structure L2 includes a second interconnect-level dielectric layer 32, which may include a stack of a via-level dielectric layer and a line-level dielectric layer over the via-level dielectric layer, or include a line-and-via-level dielectric layer. In some embodiments, the second interconnect-level structure L2 further includes a plurality of interconnect metal vias 42V and a plurality of interconnect metal lines 42M, which are collectively formed within the second interconnect-level dielectric layer 32. The interconnect metal lines 42M are formed over the interconnect metal vias 42V. In some embodiments, top surfaces of the interconnect metal lines 42M are coplanar with a top surface of the second interconnect-level dielectric layer 32.

Referring to FIG. 1B, a plurality of thin film transistors 50 are subsequently formed over the second interconnect-level structure L2. The details of the structure and the processing steps for the thin film transistors 50 are described in detail below. A third interconnect-level dielectric layer 33 may be formed during formation of the thin film transistors 50. The set of all structures formed at the level of the thin film transistors 50 is herein referred to as a third interconnect-level structure L3.

Referring to FIG. 1C, additional interconnect-level structures may be subsequently formed over the third interconnect-level structure L3 (i.e., over the thin film transistors 50), which are herein referred to as upper interconnect-level structures. As illustrated in FIG. 1C, the upper interconnect-level structures include a fourth interconnect-level structure L4 and a fifth interconnect-level structure L5, for example. In some embodiments, the fourth interconnect-level structure L4 includes a fourth interconnect-level dielectric layer 34. In some embodiments, the fourth interconnect-level structure L4 further includes a plurality of interconnect metal vias 44V and a plurality of interconnect metal lines 44M collectively formed within the fourth interconnect-level dielectric layer 34. In some embodiments, the fifth interconnect-level structure L5 includes a fifth interconnect-level dielectric layer 35. In some embodiments, the fifth interconnect-level dielectric layer 35 includes a plurality of interconnect metal vias 45V and a plurality of interconnect metal lines 45M.

Each interconnect-level dielectric layer may be referred to as an interlayer dielectric (ILD) layer 30. Each interconnect metal via and each interconnect metal line may be collectively referred to as an interconnect metal structure 40. Each contiguous combination of an interconnect metal via and an overlying interconnect metal line located within a same interconnect-level structure may be formed sequentially as two distinct structures by employing two single damascene processes, or may be simultaneously formed as a unitary structure employing a dual damascene process. Each of the metal interconnect structure 40 may include a respective metallic liner, such as a layer of titanium nitride (TiN), tantalum nitride (TaN), or tungsten nitride (WN), and a respective metallic fill material, such as tungsten (W), Cu, Co, molybdenum (Mo), ruthenium (Ru), other elemental metals, or an alloy or a combination thereof. Other suitable materials for use as a metallic liner and metallic fill material may alternatively be utilized.

Further, in some embodiments, various etching stop layers may be inserted between vertically neighboring pairs of ILD layers 30. For example, referring to FIGS. 1A-1C, a first etching stop layer ESL1 is formed between the first interconnect-level structure L1 and the second interconnect-level structure L2, a second etching stop layer ESL2 is formed between the second interconnect-level structure L2 and the third interconnect-level structure L3, a third etching stop layer ESL3 is formed between the third interconnect-level structure L3 and the fourth interconnect-level structure L4, and a fourth etching stop layer ESL4 is formed between the fourth interconnect-level structure L4 and the fifth interconnect-level structure L5. Each interconnect metal via may extend through the underlying etching stop layer to be in contact with the underlying interconnect metal line, enabling electrical connection among the exemplary structure. As illustrated in FIG. 1C, each interconnect metal via 45V penetrates through the fourth etching stop layer ESL4 and contacts a respective one of the interconnect metal lines 44M, and each interconnect metal via 42V penetrates through the first etching stop layer ESL1 and contacts a respective one of the interconnect metal lines 41M.

In some embodiments, each interconnect metal via 44V penetrates through the third etching stop layer ESL3 to contact an upper conductive portion of a respective one of the thin film transistors 50, and each lower conductive portion of the thin film transistors 50 extends through the second etching stop layer ESL2 to contact a respective one of the interconnect metal lines 42M. In some embodiments, the upper conductive portion may be a source electrode or a drain electrode of the thin film transistor and the lower conductive portion may be a gate electrode of the thin film transistor. Such thin film transistor can be referred to as a back-gated thin film transistor or a bottom-gated thin film transistor, for example.

While the present disclosure is described employing an embodiment in which thin film transistors 50 may be formed as a component of a third interconnect-level structure L3, embodiments are expressly contemplated herein in which the thin film transistors 50 may be formed as components of any other interconnect-level structure. Further, while the present disclosure is described using an embodiment in which a set of five interconnect-level structures are formed, embodiments are expressly contemplated herein in which a different number of interconnect-level structures is used. In addition, embodiments are expressly contemplated herein in which thin film transistors 50 may be provided within multiple interconnect-level structures.

Conventional thin film transistors include source and drain electrodes that contact a channel layer and overlap with a gate electrode that is separated from the channel by a gate dielectric layer. However, during manufacturing, a channel region of the channel layer may be degraded by processing conditions, for example, high-energy particle bombardment in plasma dry etching process.

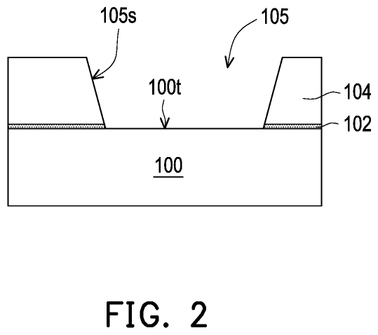

FIG. 2 through FIG. 7 are fragmentary cross-sectional views at various stages of formation of a thin film transistor 50A in accordance with some embodiments of the disclosure. It is understood that additional steps can be provided before, during, and after the method disclosed, and some of the steps described can be moved, replaced, or eliminated for additional embodiments of the method disclosed. In addition, additional features can be added in the thin film transistor depicted in FIGS. 2-7, and some of the features described below can be replaced, modified, or eliminated in other embodiments of the thin film transistor.

Referring to FIG. 2, an etching stop layer 102 and an ILD layer 104 are sequentially deposited on a substrate 100. The substrate 100 may be any suitable substrate, such as a semiconductor device substrate, and may include elements formed during FEOL processes. In an embodiment, the thin film transistors are formed as part of an interconnect structure in an integrated semiconductor device. For example, the thin film transistors are formed as part of the third interconnect-level structure L3 in which case the second interconnect level dielectric layer 32 may take the place of the substrate 100. In such a case, the second etching stop layer ESL2 and the third interconnect-level dielectric layer 33 also take the place of the etching stop layer 102 and the ILD layer 104, respectively. For simplicity of illustration, the interconnect metal vias 42V and the interconnect metal lines 42M are not shown in FIG. 2 or the following figures.

In some embodiments, the material of the etching stop layer 102 includes silicon nitride (SiN), silicon carbide (SiC), silicon oxycarbide (SiOC), silicon oxynitride (SiON), silicon carbonitride (SiCN), silicon oxycarbonitride (SiOCN), combinations thereof and/or other suitable materials. In some embodiments, the etch stop layer 102 may be formed by chemical vapor deposition (CVD), plasma-enhanced CVD (PECVD), physical vapor deposition (PVD), atomic layer deposition (ALD), or the like. In some embodiments, the ILD layer 104 includes silicon oxide, carbon-containing oxide such as SiOC, silicate glass, tetraethylorthosilicate (TEOS) oxide, un-doped silicate glass, or doped silicon oxide such as borophosphosilicate glass (BPSG), fluorine-doped silica glass (FSG), phosphosilicate glass (PSG), boron doped silicon glass (BSG), combinations thereof and/or other suitable dielectric materials. In some other embodiments, the ILD layer 104 may include low-k dielectric material with a dielectric constant lower than 4, extreme low-k (ELK) dielectric material with a dielectric constant lower than 2.5. For example, the low-k material includes a polymer-based material, such as benzocyclobutene (BCB), FLARE®, or SILK®; or a silicon dioxide-based material, such as hydrogen silsesquioxane (HSQ) or SiOF. In some embodiments, the ILD layer 104 is formed by CVD, PECVD, flowable CVD (FCVD), PVD, spin coating, or the like.

Thereafter, a gate trench 105 is formed in the etching stop layer 102 and the ILD layer 104, in accordance with some embodiments. For example, the gate trench 105 penetrates through the etching stop layer 102 and the ILD layer 104 and exposes a top surface 100t of the substrate 100. In embodiments where the substrate 100 is the second interconnect level dielectric layer 32, a top surface of a respective one of the interconnect metal lines 42M (not shown) is exposed by the gate trench 105 such that the interconnect metal line 42M is in physical and electrical contact with a later-formed gate electrode. In some embodiments, the formation of the gate trench 105 includes forming a patterned mask layer (not shown) over the ILD layer 104, anisotropic etching the ILD layer 104 using the patterned mask layer as a mask to form the gate trench 105. In some embodiments, an ashing process is used to remove the patterned mask layer after the gate trench 105 is formed. As illustrated in FIG. 2, the gate trench 105 is formed with slant sidewalls 105s. Alternatively, the gate trench 105 may include substantially vertical sidewalls.

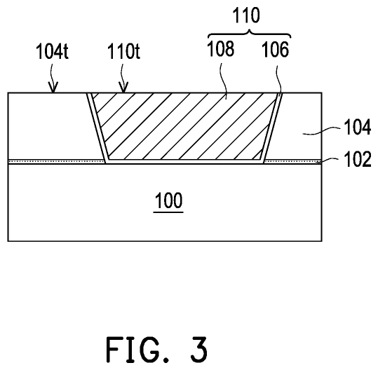

Referring to FIG. 3, a barrier material is conformally deposited over the structure shown in FIG. 2. For example, the barrier material is deposited on exposed surfaces of the substrate 100 and the ILD layer 104 and exposed sidewalls 105s of the gate trench 105 (see FIG. 2). In some embodiments, the barrier material includes Ta, Cu, Co, Mn, Mo, Ru, W, Au, Ag, TiN, TaN, WCN or combinations thereof, and may be formed by CVD, PECVD, ALD, or the like. Later, a gate fill material is deposited over the barrier material and fills a remainder of the gate trench 105. In some embodiments, the gate fill material includes Ta, Cu, Co, Mo, Ru, W, Au, Ag, TiN, TaN, WCN, combinations thereof, and/or other suitable metallic materials, and may be formed by CVD, PECVD, PVD, or the like. Alternatively, the formation of the gate fill material may include performing a plating process (such as electrochemical plating (ECP)).

Still referring to FIG. 3, a planarization process is then performed to remove excess barrier material and gate fill material, exposing a top surface 104t of the ILD layer 104. The planarization process includes, for example, a chemical mechanical polishing (CMP) process or an etch back process. The remaining barrier material forms a barrier layer 106 and the remaining gate fill material forms a gate layer 108. The combination of the barrier layer 106 and the gate layer 108 that fills the gate trench constitutes a gate electrode 110. The gate electrode 110 extends through the ILD layer 104 and the etching stop layer 102 and is in direct contact with the substrate 100 (e.g., in direct contact with the metal line therein). In some embodiments, the gate electrode 110 may be referred to as a bottom gate electrode or a back-gate electrode. As shown in FIG. 3, after the planarization process, a top surface 110t of the gate electrode 110 is substantially coplanar with the top surface 104t of the ILD layer 104.

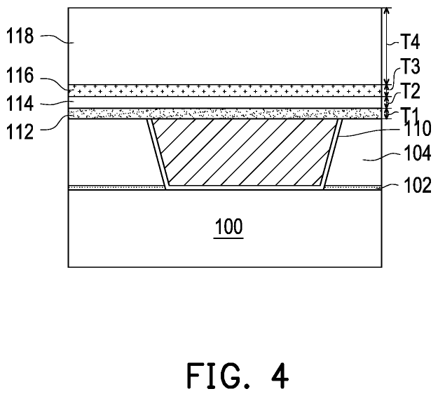

Referring to FIG. 4, a gate dielectric layer 112, a semiconducting material layer 114, a capping layer 116, and an ILD layer 118 are sequentially deposited over the ILD layer 104 and the gate electrode 110. For example, the gate dielectric layer 112 is formed covering top surfaces 104t, 110t of the ILD layer 104 and the gate electrode 110, the semiconducting material layer 114 is formed covering a top surface of the gate dielectric layer 112, the capping layer 116 is formed covering a top surface of the semiconducting material layer 114, and the ILD layer 118 is formed covering a top surface of the capping layer 116.

In some embodiments, the gate dielectric layer 112 includes high-k dielectric, such as aluminum oxide (AlOₓ), yttrium oxide (Y₂Oₓ), yttrium titanium oxide (Y₂TiOₓ), ytterbium oxide (Yb₂Oₓ), lanthanum oxide (La₂Oₓ), tantalum oxide (Ta₂Oₓ), titanium oxide (TiOₓ), hafnium oxide (HfOₓ), zirconium oxide (ZrOₓ), aluminum nitride (AlN), combinations thereof, and/or other suitable dielectric material. The gate dielectric layer 112 may be formed by CVD, PVD, ALD, or the like. In one embodiment, the gate dielectric layer 112 is formed with a thickness T1 of less than about 100 nm. In some embodiments, the semiconducting material layer 114 includes metal-oxide material such as ZnO, indium gallium zinc oxide (IGZO), indium tin oxide (ITO), or combinations thereof. In alternative embodiments, the semiconducting material layer 114 includes amorphous silicon (a-Si) or polysilicon (poly-Si). The semiconducting material layer 114 may be formed by CVD, PVD, ALD, or the like. In one embodiment, the semiconducting material layer 114 is formed with a thickness T2 of less than about 100 nm.

In some embodiments, the capping layer 116 includes a dielectric material that is capable of hindering or blocking hydrogen diffusion therethrough. In some embodiments, the material of the capping layer 116 includes AlOₓ, Y₂Oₓ, Y₂TiOₓ, Yb₂Oₓ, La₂Oₓ, Ta₂Oₓ, TiOₓ, HfOₓ, ZrOₓ, or combinations thereof. In some embodiments, the material of the capping layer 116 is different from the material of the semiconducting material layer 114, and the material of the capping layer 116 has a density higher than that of the material of the semiconducting material layer 114. In that case, the capping layer 116 may be referred to as a hydrogen-blocking dielectric layer or a hydrogen diffusion barrier layer. The capping layer 116 prevents diffusion of hydrogen into a channel region of the semiconducting material layer 114 during following processes, for example, an annealing process or an etching process. In this way, the surface electronic states within the semiconducting material layer 114 is prevented from changing, and the transistor characteristics of the thin film transistors to be formed are prevented from being shifted. In some embodiments, the capping layer 116 is formed with a thickness T3 of less than about 100 Å by CVD, PVD, ALD, or the like. Furthermore, in some embodiments, the capping layer 116 is in-situ deposited on the semiconducting material layer 114 using a suitable deposition process that is performed in the same process chamber as the deposition of the semiconducting material layer 114. For example, with the presence of the capping layer 116, hydrogen and/or water diffusion or absorption into the semiconducting material layer 114 may be avoided, and less or minimal impurities is introduced into the semiconducting material layer 114. When the capping layer 116 is formed in-situ and right after the deposition of the semiconducting material layer 114, there is no need to break the vacuum of the chamber or performing purging, the interface between the capping layer 116 and the underlying semiconducting material layer 114 is clean and free of hydrogen and water absorption. The formation of the in-situ deposited capping layer ensures good interface quality between the capping layer 116 and the underlying semiconducting material layer 114, and lower contact resistance is obtained due to such good quality interface. Further, the presence of the capping layer enlarges the process window and a better etching process control is achieved.

In accordance with some embodiments, the gate dielectric layer 112, the semiconducting material layer 114, and the capping layer 116 are patterned (using the same mask) to form a stack structure including the patterned gate dielectric layer 112, the patterned semiconducting material layer 114, and the patterned capping layer 116. Thereafter, an ILD layer 118 is formed over the capping layer 116 covering the stack structure. In some embodiments, the ILD layer 118 is formed by similar processes and dielectric materials as the ILD layer 104 described with reference to FIG. 2. In some embodiments, the ILD layer 118 is formed with a thickness T4 of less than about 100 nm.

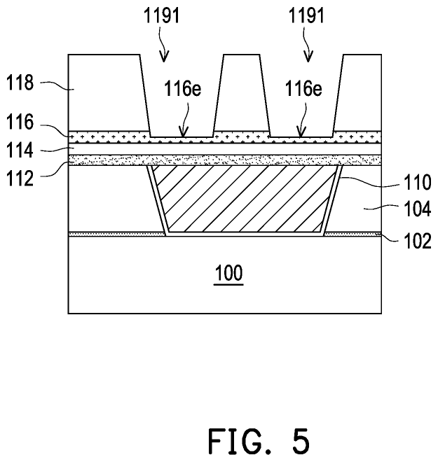

Referring to FIG. 5, a plurality of openings 1191 (only two openings are shown) is formed in the ILD layer 118. The formation of the openings 1191 includes forming a patterned mask layer (not shown) over the ILD layer 118, anisotropic etching the ILD layer 118 using the patterned mask layer as a mask to form the openings 1191. In some embodiments, the anisotropic etching process for forming the openings 1191 includes a dry etching process, such as a plasma etching process. Exemplary plasma etching processes include, but are not limited to, inductively coupled plasma (ICP), reactive ion etch (RIE), neutral beam etch (NBE), and/or combinations thereof. In some embodiments, the capping layer 116 functions as an etching stop layer during the dry etching process, so that the dry etching process stops at the capping layer 116. Thus, the underlying semiconducting material layer 114 is shielded from exposure to high-energy particle bombardment and is protected from being damaged by the plasma of the dry etching process. That is, the capping layer 116 provides at least dual functions of hydrogen hinderance as a hydrogen blocking layer and precise etching control as an etching stop layer.

In some other embodiments, during the dry etching process, over-etching occurs, so that a portion of the capping layer 116 is removed, as shown in FIG. 5, in addition to removing the intended portions of the ILD layer 118. Such over-etching process only partially removes the capping layer 116 in the thickness direction. That is, during forming the openings 1191, certain portions of the capping layer 116 are recessed and the recessed surfaces 116e of the recessed portions of the capping layer 116 are lower than the interface between the ILD layer 118 and the capping layer 116 (i.e. the original top surface of the capping layer 116).

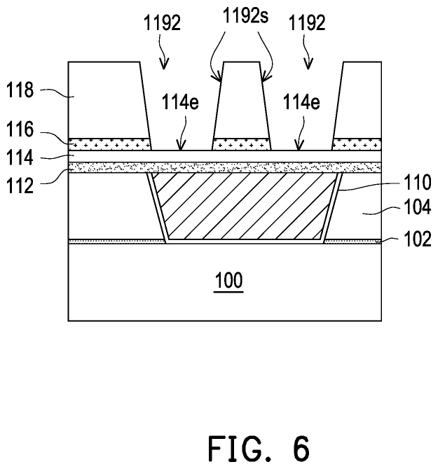

Turning to FIG. 6, a selective removal process is subsequently performed to remove portions of the capping layer 116 under the openings 1191, thereby forming a pair of contact openings 1192. In some embodiments, the selective removal process includes an isotropic etching process or a wet etching process that selectively removes portions of the capping layer 116 exposed by the openings 1191. For example, the wet etching process may utilize an etchant solution having a high etching selectivity toward the material of the capping layer 116, rather than etching the material of the semiconducting material layer 114, so that the capping layer 116 can be effectively removed without damaging the surface of the semiconducting material layer 114 or causing dishing of the semiconducting material layer 114. In some embodiments, the etching selectivity of the capping layer 116 to the semiconducting material layer 114 (i.e. the material of the capping layer 116 relative to the material of the semiconducting material layer 114) is at least larger than 5. In some embodiments, the selective removal process only removes the capping layer 116 without removing the semiconducting material layer 114.

As seen in FIG. 6, no over-etching occurs and the semiconducting material layer 114 is not damaged or recessed after the wet etching process such that an exposed surface 114e of the semiconducting material layer 114 is substantially levelled with and flush with the interface between the capping layer 116 and the semiconducting material layer 114 (i.e. the original top surface of the semiconducting material layer 114). That is, the exposed surface 114e of the semiconducting material layer 114 is recess-free or dishing-free. Also, as the material of the capping layer 116 is completely removed, the exposed surface 114e of the semiconducting material layer 114 is residue-free (free of remaining capping layer), and there is no residue of the material of the capping layer (i.e. hydrogen blocking layer) between the later formed contacts and the semiconducting material layer 114. In some embodiments, the semiconducting material layer 114 has a uniform thickness (i.e., substantially the same thickness T2 over the entire semiconducting material layer 114), and after the selective removal process, the semiconducting material layer 114 still has substantially the same thickness at regions exposed by the contact openings 1192 (contact regions) and regions not exposed by the contact openings 1192 (non-contact regions). In other words, very little or no change in thickness of the entire semiconducting material layer 114 through the contact opening forming process (i.e. after the dry etching process and after the wet etching process). In some embodiments, the thickness variation of the contact regions of the semiconducting material layer 114 is minimal or nearly zero. Further, the contact openings 1192 are formed with slant sidewalls 1192s as shown. Alternatively, the contact openings 1192 may include substantially vertical sidewalls.

By utilizing a capping layer deposited directly over the semiconducting material layer and partially etching the capping layer using a hybrid etching process (for example, sequential anisotropic-isotropic etching processes or dry-wet sequential etching processes) to form contact openings exposing the semiconducting material layer, the semiconducting material layer is protected from plasma damage and/or by-products caused by the dry etching process, and the exposed surface of the semiconducting material layer is substantially clean and planar without any recesses. Furthermore, the capping layer may also serve as a hydrogen-blocking dielectric layer to minimize the hydrogen diffusion into the semiconducting material layer during subsequent processing, which degrades the quality of the underlying layer and downgrade the performance of the device. By doing so, an improved device performance of the thin film transistor is achieved.

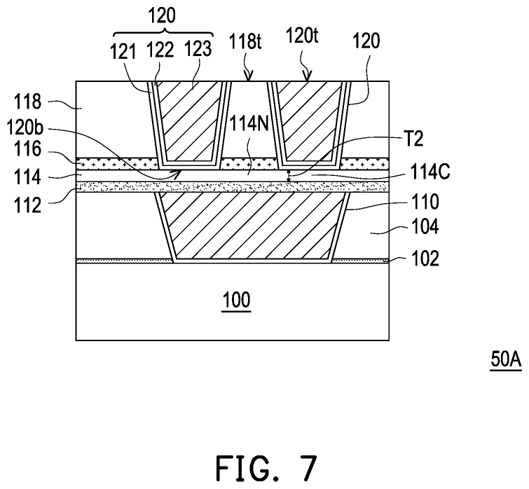

Thereafter, in FIG. 7, contact terminals 120 are formed in the contact openings 1192 and are in direct contact with the semiconducting material layer 114. Each contact terminal 120 includes a barrier layer 121 over the contact openings 1192 and conformally covering the sidewalls 1192s of the contact opening 1192 and covering the exposed surface 114e of the semiconducting material layer 114. Each contact terminal 120 further includes a seed layer 122 formed over the contact opening 1192 and on the barrier layer 121 and metallic contact 123 formed on the seed layer 122 within the contact opening 1192 and filling the contact opening 1192. In some embodiments, the barrier layer 121 is formed before forming the seed layer 122 to prevent out-diffusion of the material of the seed layer 122.

In some embodiments, a barrier material (not shown) and a seed material (not shown) are sequentially formed over the contact openings 1192 and conformally covering the exposed surface 114e of the semiconducting material layer 114 and the sidewalls 1192s of the contact openings 1192, and a metallic material (not shown) is then filled into the contact openings 1192 and on the seed material. The barrier material and the seed material may individually include one or more materials selected tungsten (W), ruthenium (Ru), molybdenum (Mo), tantalum (Ta), titanium (Ti), alloys thereof, and nitrides thereof, for example. In addition, the gate fill material may include TiN, TaN, Ta, Cu, Co, Mo, Ru W, Au, Ag, WCN, combinations thereof, and/or other suitable metallic materials. In some embodiments, the barrier material is formed by CVD, PVD or ALD. In some embodiments, the seed material is formed by CVD PVD or ALD. In some embodiments, the metallic material is formed by CVD or PVD. In alternative embodiments, the formation of the metallic material includes performing a plating process (such as ECP).

In some embodiments, a planarization process is then performed to remove excess barrier material, excess seed material, and excess metallic material. The planarization process includes, for example, a CMP process or an etch back process. The remaining barrier material forms the barrier layer 121, the remaining seed material forms the seed layer 122, and the remaining metallic material forms the metallic contact 123. The combination of the barrier layer 121, the seed layer 122, and the metallic contact 123 that fills the contact openings 1192 constitutes contact terminals 120. As seen in FIG. 7, a top surface 118t of the ILD layer 118 is substantially coplanar with top surfaces 120t of the contact terminals 120.

Still referring to FIG. 7, in some embodiments, the contact terminals 120 function as source and drain terminals of an obtained thin film transistor 50A. The semiconducting material layer 114 functions as a channel layer of the thin film transistor 50A, in accordance with some embodiments. The thin film transistor 50A includes the gate electrode 110, a stack structure over the gate electrode 110 having the gate dielectric layer 112, the semiconducting material layer 114, the capping layer 116, and the ILD layer 118 that are sequentially stacked from the bottom to the top. The thin film transistor 50A further includes contact terminals 120 which extend through the ILD layer 118 and the capping layer 116, such that bottom surfaces 120b (contact surfaces) of the contact terminals 120 are in direct contact with the semiconducting material layer 114, without the residue of the capping layer 116. Further, as shown in FIG. 7, a bottommost portion of each contact terminal 120 is surrounded by the capping layer 116. In some embodiments, the semiconducting material layer 114 has a uniform thickness T2, and for the thin film transistor 50A, the semiconducting material layer 114 has substantially the same thickness T2, either for contact portions 114C at contact regions (portions in contact with the contact terminals 120) or non-contact portions 114N of the semiconducting material layer 114.

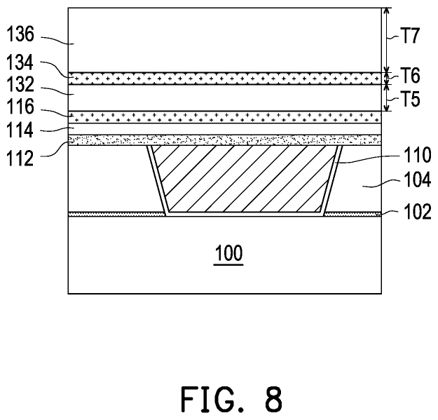

FIG. 8 through FIG. 13 are fragmentary cross-sectional views at various stages of formation of a thin film transistor 50B in accordance with some embodiments of the disclosure. It is understood that additional steps can be provided before, during, and after the method disclosed, and some of the steps described can be moved, replaced, or eliminated for additional embodiments of the method disclosed. In addition, additional features can be added in the thin film transistor depicted in FIGS. 8-13, and some of the features described below can be replaced, modified, or eliminated in other embodiments of the thin film transistor. In addition, since the thin film transistor 50B is similar to the thin film transistor 50A in FIG. 7, the elements similar to or substantially the same as the elements described previously will use the same reference numbers, and certain details or descriptions of the same elements may not be repeated herein.

Referring to FIG. 8, subsequent to the formation of the gate electrode 110 and the deposition of the gate dielectric layer 112, the semiconducting material layer 114, and the capping layer 116, a first ILD layer 132, an additional capping layer 134, and a second ILD layer 136 are sequentially deposited on the capping layer 116. In some embodiments, the first ILD layer 132 and the second ILD layer 136 includes similar materials formed by similar methods as the ILD layer 118 described above with reference to FIG. 4. In some embodiments, the capping layer 134 includes similar materials formed by similar methods as the capping layer 116 described above with reference to FIG. 4. In one embodiment, the capping layer 134 includes substantially the same material as the capping layer 116. In some other embodiments, the capping layer 134 includes a material different from that of the capping layer 116.

Further, in some embodiments, the second ILD layer 136 is formed to be thicker than the first ILD layer 134, and the capping layer 132 is formed to be thicker than the capping layer 116. For example, the first ILD layer 132 is formed with a thickness T5 of less than about 50 nm, and the second ILD layer 136 is formed with a thickness T7 of less than about 100 nm. As described above, in some embodiments, the capping layer 116 is formed with a thickness T3 of less than about 100 Å (see FIG. 4), and the additional capping layer 134 between the first ILD layer 132 and the second ILD layer 136 is formed with a thickness T6 of less than about 50 nm.

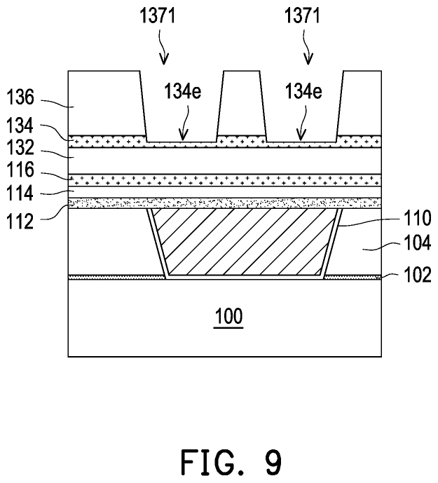

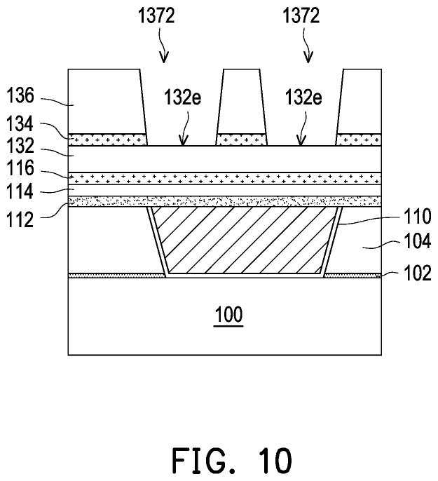

Referring to FIG. 9 and FIG. 10, a first hybrid etching process is performed to expose portions of the first ILD layer 132. In some embodiments, a dry etching process such as ICP, RIE, NBE is performed to form first openings 1371. For example, the dry etching process etches through the second ILD layer 136 such that the first openings 1371 penetrate through the second ILD layer 136. In addition, over-etching may occur during the dry etching process, so that the capping layer 134 may be partially removed in the thickness direction. That is, portions of the capping layer 134 are recessed and the recessed surfaces 134e of the recessed portions of the capping layer 134 are lower than the interface between the second ILD layer 136 and the capping layer 134 (i.e. the original top surface of the capping layer 134).

A wet etching process is then performed to selectively remove portions of the capping layer 134 under the first openings 1371 after the dry etching process, thereby forming second openings 1372. In some embodiments, the wet etching process is performed using an etchant solution having high etching selectivity toward the material of the capping layer 134, rather than etching the material of the first ILD layer 132 so that the capping layer 134 can be effectively removed without damaging the surface of the first ILD layer 132 or causing dishing of the first ILD layer 132. In some embodiments, the etching selectivity of the capping layer 134 to the first ILD layer 132 (i.e. the material of the capping layer 134 relative to the material of the first ILD layer 132) is larger than 5. In some embodiments, the wet etching process only removes the capping layer 134 without removing the first ILD layer 132.

As seen in FIG. 10, no over-etching occurs and the first ILD layer 132 is not damaged or recessed after the wet etching process such that an exposed surface 132e of the first ILD layer 132 is substantially levelled with and flush with the interface between the capping layer 134 and the first ILD layer 132 (i.e. the original top surface of the first ILD layer 132). In some embodiments, the first ILD layer 132 has a uniform thickness (i.e., substantially the same thickness T5 over the entire first ILD layer 132), and after the selective removal process, the first ILD layer 132 still has substantially the same thickness at regions exposed by the second openings 1372 and regions not exposed by the second openings 1372. In other words, very little or no change in thickness of the entire first ILD layer 132 through the opening forming process (i.e. after the dry etching process and after the wet etching process).

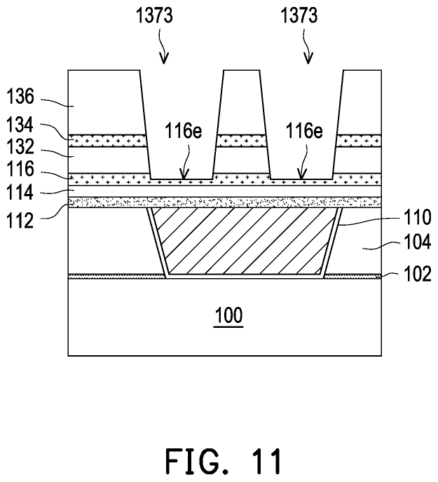

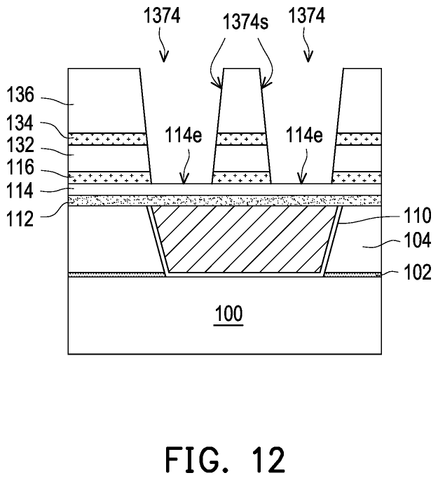

Thereafter, referring to FIG. 11 and FIG. 12, a second hybrid etching process is performed to form contact openings 1374. For example, a dry etching process such as ICP, RIE, NBE is performed first to form third openings 1373, and then a wet etching process is performed to form the contact openings 1374. In some embodiments, the third openings 1373 penetrates through the first ILD layer 132. In certain embodiments where over-etching occurs, the third openings 1373 further penetrates to portions of the capping layer 116, as shown in FIG. 11. In such embodiments, portions of the capping layer 116 are recessed and the recessed surfaces 116e of the recessed portions of the capping layer 116 are lower than the interface between the semiconducting material layer 114 and the capping layer 116 (i.e. the original top surface of the capping layer 116).

In accordance with some embodiments, portions of the capping layer 116 under the third openings 1373 are selectively removed using a wet etching process, thereby forming the contact openings 1374. In some embodiments, the wet etching process for forming the contact openings 1374 is substantially the same as the wet etching process for forming the contact openings 1192 as described above with reference to FIG. 6, and thus the description is not repeated herein. As seen in FIG. 12, the capping layer 116 is effectively removed without damaging the surface of the semiconducting material layer 114 or causing dishing of the semiconducting material layer 114. In some embodiments, the wet etching process only removes the capping layer 116 without removing the semiconducting material layer 114.

As seen in FIG. 12, no over-etching occurs and the semiconducting material layer 114 is not damaged or recessed after the wet etching process such that an exposed surface 114e of the semiconducting material layer 114 is substantially levelled with and flush with the interface between the capping layer 116 and the semiconducting material layer 114 (i.e. the original top surface of the semiconducting material layer 114). That is, the exposed surface 114e of the semiconducting material layer 114 is recess-free or dishing-free. Also, as the material of the capping layer 116 is completely removed, the exposed surface 114e of the semiconducting material layer 114 is residue-free (free of remaining capping layer), and there is no residue of the material of the capping layer (i.e. hydrogen blocking layer) between the later formed contacts and the semiconducting material layer 114.

In some embodiments, the semiconducting material layer 114 has a uniform thickness (i.e., substantially the same thickness T2 over the entire semiconducting material layer 114), and after the selective removal process, the semiconducting material layer 114 still has substantially the same thickness at regions exposed by the contact openings 1374 (contact regions) and regions not exposed by the contact openings 1374 (non-contact regions). In other words, very little or no change in thickness of the entire semiconducting material layer 114 through the contact opening forming process (i.e. after the dry etching process and after the wet etching process). In some embodiments, the thickness variation of the contact regions of the semiconducting material layer 114 is minimal or nearly zero. Further, the contact openings 1374 are formed with slant sidewalls 1374s as shown. Alternatively, the contact openings 1374 may include substantially vertical sidewalls.

As mentioned above, the capping layer formed directly on the semiconducting material layer can act as both an etching stop layer and a hydrogen-blocking dielectric layer to protect the underlying semiconducting material layer from plasma damage or possible recess therein and to minimize the hydrogen diffusion into the semiconducting material layer. Furthermore, by adding an additional second ILD layer over the first ILD layer and an additional capping layer between the first and second ILD layer, not only can hydrogen be effectively prevented from diffusing into the semiconducting material layer, but the contact openings are formed by two hybrid etching processes, which can further reduce by-products generated by the dry etching process. More specifically, the first ILD layer is formed much thinner than the second ILD layer, such that the dry etching process of the second hybrid etching process can be performed in a shorter time, thereby generating fewer by-products.

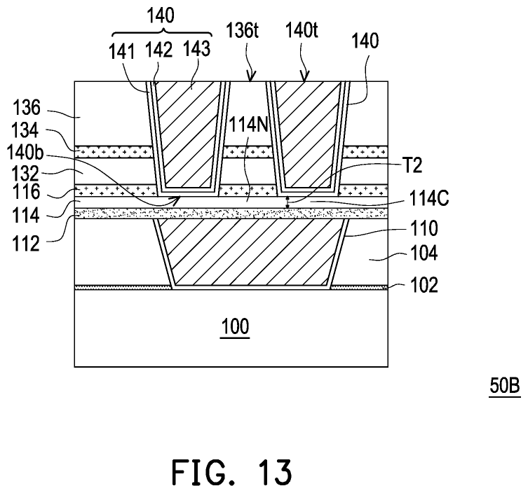

Referring to FIG. 13, contact terminals 140 are formed in the contact openings 1374 and are in direct contact with the semiconducting material layer 114. Each contact terminal 140 includes a barrier layer 141 over the contact openings 1374 and conformally covering the sidewalls 1374s of the contact opening 1374 and covering the exposed surface 114e of the semiconducting material layer 114. Each contact terminal 140 further includes a seed layer 142 formed over the contact opening 1374 and on the barrier layer 141 and metallic contact 143 formed on the seed layer 142 within the contact opening 1374 and filling the contact opening 1374.

In some embodiments, the barrier layer 141 includes similar materials formed by similar methods as the barrier layer 121, the seed layer 142 includes similar materials formed by similar methods as the seed layer 122, and the metallic contact 143 includes similar materials formed by similar methods as the metallic contact 123, and thus the description is not repeated herein. The combination of the barrier layer 141, the seed layer 142, and the metallic contact 143 that fills the contact openings 1374 constitutes contact terminals 140. In some embodiments, a top surface 136t of the second ILD layer 136 is substantially coplanar with top surfaces 140t of the contact terminals 140 after performing a planarization process, as shown in FIG. 13.

In some embodiments, the contact terminals 140 function as source and drain terminals of an obtained thin film transistor 50B. The semiconducting material layer 114 functions as a channel layer of the thin film transistor 50B, in accordance with some embodiments. The thin film transistor 50B includes the gate electrode 110, a stack structure over the gate electrode 110 having the gate dielectric layer 112, the semiconducting material layer 114, the capping layer 116, the first ILD layer 132, the capping layer 134, and the second ILD layer 136 that are sequentially stacked from the bottom to the top. The thin film transistor 50B further includes the contact terminals 140 which extend through the first and second ILD layer 132, 136, the capping layer 134 between the first and second ILD layer 132, 136, and the capping layer 116, such that bottom surfaces 140b of the contact terminals 140 (contact surfaces) are in direct contact with the semiconducting material layer 114. Further, as shown in FIG. 13, a bottommost portion of each contact terminal 140 is surrounded by the capping layer 116. In some embodiments, the semiconducting material layer 114 has a uniform thickness T2, and for the thin film transistor 50B, the semiconducting material layer 114 has substantially the same thickness T2, either for contact portions 114C at contact regions (portions in contact with the contact terminals 140) or non-contact portions 114N of the semiconducting material layer 114.

In accordance with an embodiment of the disclosure, a semiconductor device is described. The semiconductor device includes a semiconducting material layer, a gate electrode disposed under the semiconducting material layer, a pair of contact terminals disposed over the semiconducting material layer, and a hydrogen-blocking dielectric layer disposed on the semiconducting material layer. The pair of contact terminals penetrates through the hydrogen-blocking dielectric layer to be in contact with the semiconducting material layer at a contact surface, and the contact surface is substantially coplanar with and levelled with an interface between the hydrogen-blocking dielectric layer and the semiconducting material layer.

In accordance with an embodiment of the disclosure, a semiconductor device is described. The semiconductor device includes a semiconductor device substrate, a thin film transistor disposed over the semiconductor device substrate, and an upper interconnect structure disposed over the thin film transistor. The thin film transistor includes a gate electrode, source and drain electrodes, a gate dielectric layer and a channel layer disposed between the gate electrode and the source and drain electrodes, and a first capping layer disposed over the channel layer and away from the gate dielectric layer. The gate electrode is in contact with a portion of the gate dielectric layer and the source and drain electrodes are in contact with portions of the channel layer, and contact portions of the channel layer have a thickness substantially equivalent to a thickness of non-contact portions of the channel layer. The first capping layer surrounds portions of the source and drain electrodes closest to the channel layer.

In accordance with yet another embodiment of the disclosure, a method for forming a semiconductor device is described. The method includes at least the following steps. A gate electrode is formed in a first dielectric layer over a substrate. A gate dielectric layer is formed over the gate electrode and the first dielectric layer. A semiconducting material layer is formed over the gate dielectric layer. A blocking dielectric layer is formed over the semiconducting material layer. A second dielectric layer is formed over the blocking dielectric layer. A hybrid etching process is performed to etch through the second dielectric layer and the blocking dielectric layer to expose a top surface of the semiconducting material layer without recessing the semiconducting material layer and to form contact openings. Contact terminals are formed within the contact openings, and the contact terminals are in direct contact with the exposed top surface of the semiconducting material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconducting material layer;
a gate electrode disposed under the semiconducting material layer;
a pair of contact terminals disposed over the semiconducting material layer; and
a hydrogen-blocking dielectric layer disposed on the semiconducting material layer, wherein the pair of contact terminals penetrates through the hydrogen-blocking dielectric layer to be in contact with the semiconducting material layer at a contact surface, and the contact surface is substantially coplanar with and levelled with an interface between the hydrogen-blocking dielectric layer and the semiconducting material layer.

2. The semiconductor device of claim 1, wherein there is no hydrogen-blocking dielectric layer located on the contact surface and the contact surface is recess-free.

3. The semiconductor device of claim 1, further comprising a gate dielectric layer disposed between the semiconducting material layer and the gate electrode.

4. The semiconductor device of claim 1, wherein lower portions of sidewalls of the pair of contact terminals are surrounded by the hydrogen-blocking dielectric layer.

5. The semiconductor device of claim 4, further comprising a first interlayer dielectric layer deposed on the hydrogen-blocking dielectric layer, wherein the pair of contact terminals penetrates through the first interlayer dielectric layer.

6. The semiconductor device of claim 5, wherein upper portions of the sidewalls of the pair of contact terminals are surrounded by the first interlayer dielectric layer.

7. The semiconductor device of claim 5, further comprising:
a second interlayer dielectric layer disposed over the first interlayer; and
a capping layer disposed between the first interlayer dielectric layer and the second interlayer dielectric layer, wherein the pair of contact terminals penetrates through the second interlayer dielectric layer and the capping layer.

8. The semiconductor device of claim 7, wherein the second interlayer dielectric layer is thicker than the first interlayer dielectric layer.

9. The semiconductor device of claim 7, wherein a thickness of the capping layer is larger than a thickness of the hydrogen-blocking dielectric layer.

10. A semiconductor device, comprising:
a semiconductor device substrate;
a thin film transistor disposed over the semiconductor device substrate, the thin film transistor comprising:
a gate electrode;
source and drain electrodes;
a gate dielectric layer and a channel layer disposed between the gate electrode and the source and drain electrodes, the gate electrode being in contact with a portion of the gate dielectric layer and the source and drain electrodes being in contact with portions of the channel layer, wherein contact portions of the channel layer have a thickness substantially equivalent to a thickness of non-contact portions of the channel layer; and
a first capping layer disposed over the channel layer and away from the gate dielectric layer, the first capping layer surrounding portions of the source and drain electrodes closest to the channel layer; and
an upper interconnect structure disposed over the thin film transistor.

11. The semiconductor device of claim 10, wherein the thin film transistor further comprises a first interlayer dielectric layer disposed on the first capping layer and surrounding the source and drain electrodes, and a material of the first capping layer has a density higher than that of a material of the first interlayer dielectric layer.

12. The semiconductor device of claim 11, wherein the thin film transistor further comprises:
a second capping layer disposed over the first interlayer dielectric layer; and
a second interlayer dielectric layer disposed over the second capping layer,
wherein the second capping layer and the second interlayer dielectric layer surrounds the source and drain electrodes, and a material of the second capping layer has a density higher than that of a material of the second interlayer dielectric layer.

13. The semiconductor device of claim 12, wherein the second capping layer and the first capping layer are made of a same material.

14. The semiconductor device of claim 12, wherein a material of the second capping layer is different from a material of the first capping layer.

15. The semiconductor device of claim 10, wherein the semiconductor device substrate comprises a lower interconnect structure, and the thin film transistor is electrically connected to the upper interconnect structure and the lower interconnect structure.

16. A method for forming a semiconductor device, comprising:
forming a gate electrode in a first dielectric layer over a substrate;
forming a gate dielectric layer over the gate electrode and the first dielectric layer;
forming a semiconducting material layer over the gate dielectric layer;
forming a blocking dielectric layer over the semiconducting material layer;
forming a second dielectric layer over the blocking dielectric layer;
performing a hybrid etching process etching through the second dielectric layer and the blocking dielectric layer to expose a top surface of the semiconducting material layer without recessing the semiconducting material layer and to form contact openings; and
forming contact terminals within the contact openings, wherein the contact terminals are in direct contact with the exposed top surface of the semiconducting material layer.

17. The method of claim 16, wherein performing the hybrid etching process comprising:
performing a dry etching process to remove and etch through the second dielectric layer; and
performing a wet etching process to etch through the blocking dielectric layer without damaging the semiconducting material layer.

18. The method of claim 17, wherein the dry etching process is performed to etch through the second dielectric layer and over-etch upper portions of the blocking dielectric layer.

19. The method of claim 17, wherein the wet etching process has an etching selectivity larger than 5 toward the blocking dielectric layer to the semiconducting material layer.

20. The method of claim 16, wherein the blocking dielectric layer is formed directly on the semiconducting material layer by an in-situ deposition process.
